(19) United States
(12) Patent Application Publication
(10) Pub. No.: US 2013/0065075 A1
(43) Pub. Date: Mar. 14, 2013

(54) MAGNETORESISTIVE SPIN VALVE LAYER SYSTEMS

(71) Applicants: Klemens Pruegl, Regensburg (DE); Juergen Zimmer, Neubiberg (DE); Andreas Strasser, Regensburg (DE); Wolfgang Raberg, Sauerlach (DE); Thomas Bever, Munich (DE)

(72) Inventors: Klemens Pruegl, Regensburg (DE); Juergen Zimmer, Neubiberg (DE); Andreas Strasser, Regensburg (DE); Wolfgang Raberg, Sauerlach (DE); Thomas Bever, Munich (DE)

(21) Appl. No.: 13/230,123

(22) Filed: Sep. 12, 2011

(51) Int. Cl. G01R 33/09; B05D 1/36; B32B 15/04

(52) U.S. Cl. 428/611; 428/457; 428/336; 427/404

(57) ABSTRACT

Embodiments relate to magnetoresistive (MR) sensors, sensor elements and structures, and methods. In particular, embodiments relate to MR, such as giant MR (GMR) or tunneling MR (TMR), spin valve layer systems and related sensors having improved stability. Embodiments include at least one of a multi-layer pinned layer or a multi-layer reference layer, making the stack more stable and therefore suitable for use at higher temperatures and magnetic fields than conventional systems and sensors.

### TECHNICAL FIELD

The invention relates generally to integrated circuit (IC) sensors and more particularly to magnetoresistive spin valve layer systems having increased stability.

### BACKGROUND

In magnetoresistive spin valve layer systems, the electrical resistance of the layer system is dependent on the angle between two magnetization directions. Referring to the conventional giant magnetoresistive (GMR) spin valve layer stack of FIG. 1, one of these directions is free, following an externally applied magnetic field. The layer associated with this direction is referred to as the free layer. While a GMR stack is depicted in FIG. 1, other magnetoresistive technologies can be used in embodiments, such as tunneling magnetoresistive (TMR).

The other magnetization direction is fixed and associated with a so-called reference layer. The reference layer is part of a reference system that also includes the antiferromagnet, pinned, and ruthenium (Ru) layers. Conventionally, the pinned and reference layers are homogenous, consisting of a cobalt iron (CoFe) or cobalt iron boron (CoFeB) alloy, for example. A purpose of the reference system is to keep the fixed magnetization direction of the reference layer as stable as possible.

The magnetization typically is fixed in the reference layer of the spin valve layer system by a coupling of the magnetization of a ferromagnet to an antiferromagnet. The layer system is then subjected to a heat treatment in the magnetic field, with the magnetization direction adjacent to the antiferromagnet being fixed after the system is cooled.

A magnetoresistive sensor using such a spin valve layer system can then be used up to some maximum temperature and maximum magnetic field. If the sensor is exposed to higher temperatures or magnetic fields, however, the fixed magnetization direction can be altered, leading to improper sensor operation. This limited range can be a significant drawback in some applications. For example, stronger magnets can help to reduce noise but cannot be used if these magnets will affect proper operation of the sensor.

Therefore, a need remains for improved magnetoresistive spin valve layer systems and related sensors that can be used at higher temperatures and magnetic fields.

### SUMMARY

Embodiments relate to magnetoresistive spin valve layer systems and sensors.

In an embodiment, a magnetoresistive (MR) spin valve layer stack comprises an antiferromagnet layer; a multi-layer pinned layer adjacent the antiferromagnet layer; a multi-layer reference layer; a nonmagnetic metal layer between the multi-layer pinned layer and the multi-layer reference layer; a free layer; and a nonmagnetic metal layer between the free layer and the multi-layer reference layer.

In an embodiment, a method of forming a giant magnetoresistive (GMR) spin valve layer stack comprises forming a seed layer; forming a free layer, a first side of the free layer being adjacent a first side of the seed layer; forming a copper (Cu) layer, a first side of the Cu layer being adjacent a second side of the free layer; forming a multi-layer reference layer, a first side of the multi-layer reference layer being adjacent a second side of the Cu layer; forming a nonmagnetic metal layer, a first side of the nonmagnetic metal layer being adjacent a second side of the multi-layer reference layer; forming a multi-layer pinned layer, a first side of the multi-layer pinned layer being adjacent a second side of the nonmagnetic metal layer; forming an antiferromagnet layer, a first side of the antiferromagnet layer being adjacent a second side of the multi-layer pinned layer; and forming a cap layer, a first side of the cap layer being adjacent a second side of the antiferromagnet layer.

In an embodiment, a method of forming a tunneling magnetoresistive (TMR) spin valve layer stack comprises forming a seed layer; forming a free layer, a first side of the free layer being adjacent a first side of the seed layer; forming an insulating layer, a first side of the insulating layer being adjacent a second side of the free layer; forming a multi-layer reference layer, a first side of the multi-layer reference layer being adjacent a second side of the insulating layer; forming a nonmagnetic metal layer, a first side of the nonmagnetic metal layer being adjacent a second side of the multi-layer reference layer; forming a multi-layer pinned layer, a first side of the multi-layer pinned layer being adjacent a second side of the nonmagnetic metal layer; forming an antiferromagnet layer, a first side of the antiferromagnet layer being adjacent a second side of the multi-layer pinned layer; and forming a cap layer, a first side of the cap layer being adjacent a second side of the antiferromagnet layer.

In an embodiment, a magnetoresistive (MR) spin valve layer stack comprises a free layer adjacent the seed layer; a non-magnetic layer adjacent the free layer; a reference system adjacent the non-magnetic layer and comprising a reference layer, a nonmagnetic metal layer and a pinned layer, at least one of the reference layer or the pinned layer being a multi-layer; and an antiferromagnet layer adjacent the reference system.

### BRIEF DESCRIPTION OF THE DRAWINGS

The invention may be more completely understood in consideration of the following detailed description of various embodiments of the invention in connection with the accompanying drawings, in which:

FIG. 1 is a block diagram of a conventional top spin valve layer stack.

FIG. 2 is a block diagram of a GMR top spin valve layer stack according to an embodiment.

FIG. 3 is a block diagram of a GMR top spin valve layer stack according to an embodiment.

FIG. 4 is a block diagram of a TMR top spin valve layer stack according to an embodiment.

FIG. 5 is a block diagram of a TMR top spin valve layer stack according to an embodiment.

FIG. 6 is a block diagram of a stress test methodology according to an embodiment.

FIG. 7 is a block diagram of a bottom spin valve layer stack.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

Embodiments relate to magnetoresistive spin valve layer systems and related sensors having improved stability. Embodiments comprise at least one of a multi-layer pinned layer or a multi-layer reference layer, making the stack more stable and therefore suitable for use at higher temperatures and magnetic fields than conventional systems and sensors.

Referring to FIG. 2, a top spin valve layer stack 100 according to an embodiment is depicted. In contrast with a conventional stack, stack 100 comprises a multi-layer pinned layer 102 and a multi-layer reference layer 104. While stack 100 is depicted with both pinned layer 102 and reference layer 104 being multi-layered, other embodiments can comprise only one multi-layer, with one of either pinned layer 102 or reference layer 104 being multi-layered. In the examples discussed herein, however, an embodiment in which both are multi-layered will be used.

In FIG. 2, pinned layer 102 comprises two layers, pinned layer 1 and pinned layer 2. In other embodiments, pinned layer 102 can comprise more than two multi-layers. In one embodiment, pinned layer 1 comprises CoFe and pinned layer 2 comprises nickel iron (NiFe), though these can be reversed in another embodiment. The layers of pinned layer 102 can have the same or substantially the same magnetization directions. In embodiments, at least one layer of pinned layer 102 comprises a material different from a material of one or more other layers of pinned layer 102. At least one inner layer of pinned layer 102, which is not adjacent to the antiferromagnet, comprises, in embodiments, a first material having a magnetic coupling characteristic with respect to the antiferromagnet at a weaker level than that of a coupling characteristic of a second material of the layer which interfaces the antiferromagnet. In other words, if, for example, for material testing, geometrically identical layers of the first material and the second material would interface the antiferromagnet, the first material would have a weaker magnetic coupling with the antiferromagnet than the second material.

Pinned layer 102 comprising a double layer of NiFe and CoFe can provide a more stable reference system than a single-layer system comprising NiFe or CoFe. For example, pinned layer 102 can be more stable with respect to degrading of the magnetization direction from external fields. Experimental results have shown that NiFe forms a stronger magnetic coupling of pinned layer 102 to the antiferromagnet than CoFe. By contrast, the magnetic coupling of the ruthenium (Ru) layer is intensified if the adjacent ferromagnets comprise CoFe. The Ru layer can comprise other materials in embodiments, such as other nonmagnetic metals suitable for adjacent magnetic layers to have an antiparallel magnetization orientation. Examples include iridium (Ir), copper (Cu), rhodium (Rh), osmium (Os), chromium molybdenum (CrMo) and other suitable materials.

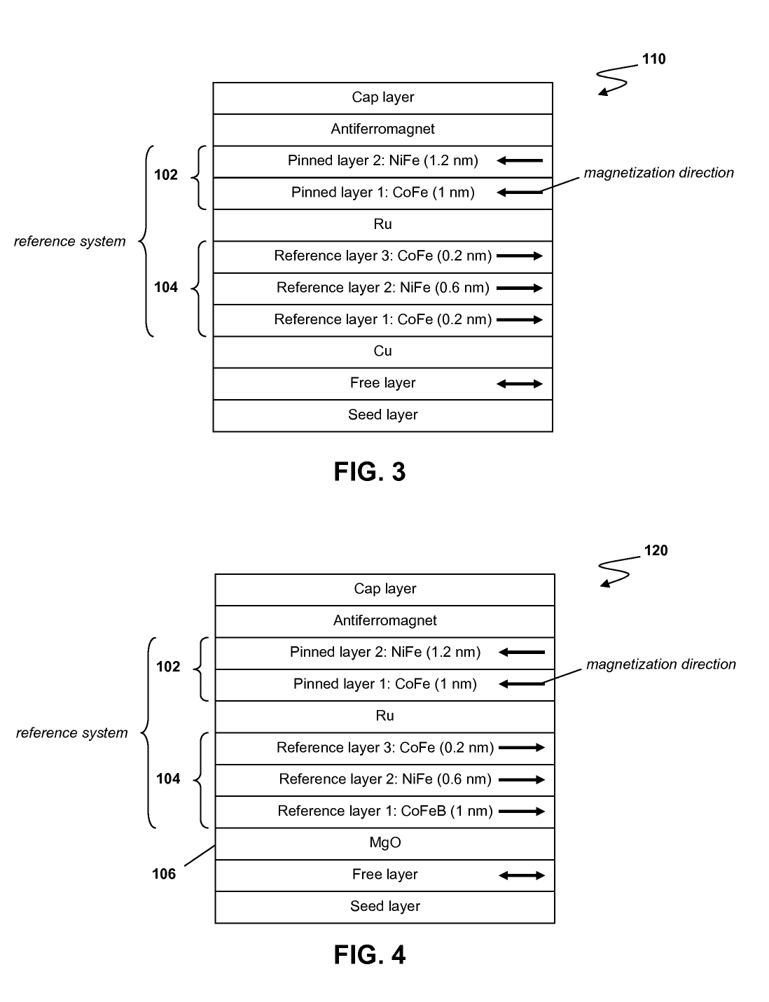

Reference layer 104 comprises three layers in the embodiment of FIG. 2, reference layer 1, reference layer 2 and reference layer 3, though reference layer 104 can comprise more or fewer layers in other embodiments. The layers of reference layer 104 can have the same or substantially the same magnetization direction as shown in FIG. 2. At least one layer of reference layer 104 can comprise a material different than the material of other layers of reference layer 104. In embodiments, the layers of reference layer 104 can comprise, for example, CoFe, NiFe and/or CoFeB. For example, and referring to FIG. 3, a stack 110 includes reference layer 1 comprising CoFe and about 0.2 nanometers (nm) thick, reference layer 2 comprising NiFe and about 0.6 nm thick and reference layer 3 comprising CoFe and 0.2 nm thick in one embodiment. In yet another embodiment, pinned layer 102 is configured similar to FIG. 3, with reference layer 104 comprising a single CoFe layer about 1.3 nm thick.

As previously mentioned, the materials and/or thicknesses can vary. For example, in various embodiments, including those related to TMR spin valve stacks discussed herein below, pinned layer 102 is about 0.4 to about 4 nm thick, and reference layer 104 is about 0.9 to about 5 nm. Individual multi-layers of pinned layer 102 (e.g., pinned layer 1 or pinned layer 2) can each be about 0.2 nm to about 2 nm. Reference layers 1 and 3 can each be about 0.2 to about 1.5 nm, while reference layer 2 is about 0.5 nm to about 2 nm in embodiments. Thicknesses of other layers in stacks 100 and 110 as well as those of other embodiments can also have thicknesses in the following example ranges: cap layer of about 2 nm to about 20 nm; antiferromagnet layer from about 10 nm to about 50 nm; Ru layer of about 0.7 nm to about 0.9 nm; copper (Cu) layer of about 1.5 nm to about 4 nm; free layer of about 1 nm to about 10 nm; and seed layer of about 1 nm to about 10 nm. Thus, overall thickness of stacks 100 and 110 can be about 17 nm to about 100 nm or more in embodiments. The particular thicknesses of each layer and/or multi-layer can depend, as appreciated by those skilled in the art, on the particular materials used, stack configurations implemented, and technologies, i.e., GMR versus TMR.

While embodiments can comprise a stack having a multi-layer pinned layer 102 and a single-layer reference layer, wherein the single-layer reference layer can comprise CoFe of about 1 to about 4 nm thick, challenges can exist according to current manufacturing processes and technologies. For example, the double-layer pinned layer 102 depicted in FIG. 2 can stabilize the reference system if the magnetization process is performed in a very strong magnetic field, e.g., greater than 1 Tesla (T). In such a high magnetic field, the magnetizations of all the ferromagnetic layers are oriented parallel to the magnetic field. Pinned layer 102 is therefore written in the desired magnetization direction.

Angle sensors, however, often consist of resistor bridges of layer stacks, the individual resistors of which are magnetized in different directions and which are physically very close together. During the production of such resistor bridges, the available magnetic fields are therefore restricted to low values for practical reasons. If the magnetization process takes place in weak magnetic fields, only the larger of the two magnetic moments of pinned layer 102 and reference layer 104 is oriented parallel to the external magnetic field. By contrast, the magnetization of the layer having the smaller magnetic moment points in the opposite direction because of the coupling of the Ru layer.

If pinned layer 102 and reference layer 104 do not comprise the same material, then the direction of the net moment of the reference system also depends on the temperature. NiFe exhibits a significantly greater decrease in magnetization with an increase in temperature than CoFe, for example, in the temperature range used. As a result, the net moment of the reference system can rotate its sign during cooling in the writing process, and a reference system written in an undefined manner can be obtained as a result.

To overcome this disadvantage, reference layers 104 can comprise NiFe in embodiments. In one embodiment, reference layer 2 comprises NiFe. As previously discussed, CoFe is used in embodiments at the interface with the Ru layer to provide a strong antiferromagnetic coupling. On the other side of reference layer 104, adjacent the Cu layer, NiFe can be disadvantageous because of the tendency of NiFe and Cu to intermix.

In other words, it can be advantageous in embodiments for both interface portions of reference layer 104, i.e., reference layers 1 and 3 as depicted in FIG. 2, to comprise CoFe. To then compensate for the temperature response of the NiFe in pinned layer 102 in embodiments, at least one inner layer of the reference layer 104, such as the center of reference layer 104, reference layer 2, comprises NiFe in such embodiments. It can be advantageous in embodiments if the layer of reference layer 104 that interfaces the Ru layer and the layer of the pinned layer 102 which interfaces the Ru layer comprise the same material, such as CoFe, to enhance stability.

The stability of the reference system is enhanced in embodiments if the magnetic moment of pinned layer 102 and that of reference layer 104 compensate for one another. As previously discussed, however, this configuration cannot be written in weak magnetic fields. A solution can exist in embodiments if pinned layer 102 and reference layer 104 comprise different materials having different Curie temperatures. For example, one of the layers of reference layer 104 can comprise a material that is not included in the layers of pinned layer 102. In such a spin valve configuration, the magnetic moments of pinned layer 102 and of reference layer 104 have different temperature responses. Therefore, it is possible to design a spin valve having a virtually compensated reference system in a typical operating temperature range, such as about −40 degrees Celsius to about 150 degrees Celsius, and a non-compensated reference system in a typical wiring temperature range, such as about 260 degrees Celsius to about 340 degrees Celsius.

In other embodiments, modifications can be made to accommodate TMR technology instead of GMR as generally discussed to this point. TMR spin valve systems are similar to GMR spin valves except that an insulating layer is used in place of the Cu layer to function as a tunnel barrier. To obtain optimum sensor properties, adaptations can also be made to the tunnel barrier/reference layer interface.

Referring to FIG. 4, an example TMR spin valve layer stack 120 is depicted. Similar to other embodiments discussed and depicted herein with respect to GMR spin valve stacks, stack 120 comprises a multi-layer pinned layer 102 and a multi-layer reference layer 104, though other embodiments can comprise more or fewer multi-layers, as well as different layer and/or multi-layer thicknesses, than depicted in the embodiment of FIG. 4. For example, as discussed above, embodiments can comprise a stack having a multi-layer pinned layer 102 and a single-layer reference layer, wherein the single-layer reference layer can comprise CoFeB of about 1 to about 4 nm thick. The Ru layer can also comprise other materials, such as Ir, Cu, Rh, Os and CrMo, for example.

As depicted in FIG. 4, however, pinned layer 102 comprises pinned layer 1 of CoFe about 1 nm thick and pinned layer 2 of NiFe about 1.2 nm thick. Reference layer 104 comprises reference layer 1 of CoFeB about 1 nm thick, reference layer 2 of NiFe about 0.6 nm thick and reference layer 3 of CoFe about 0.2 nm thick. Adjacent reference layer 1 is a tunnel barrier 106 comprising magnesium oxide (MgO) in an embodiment.

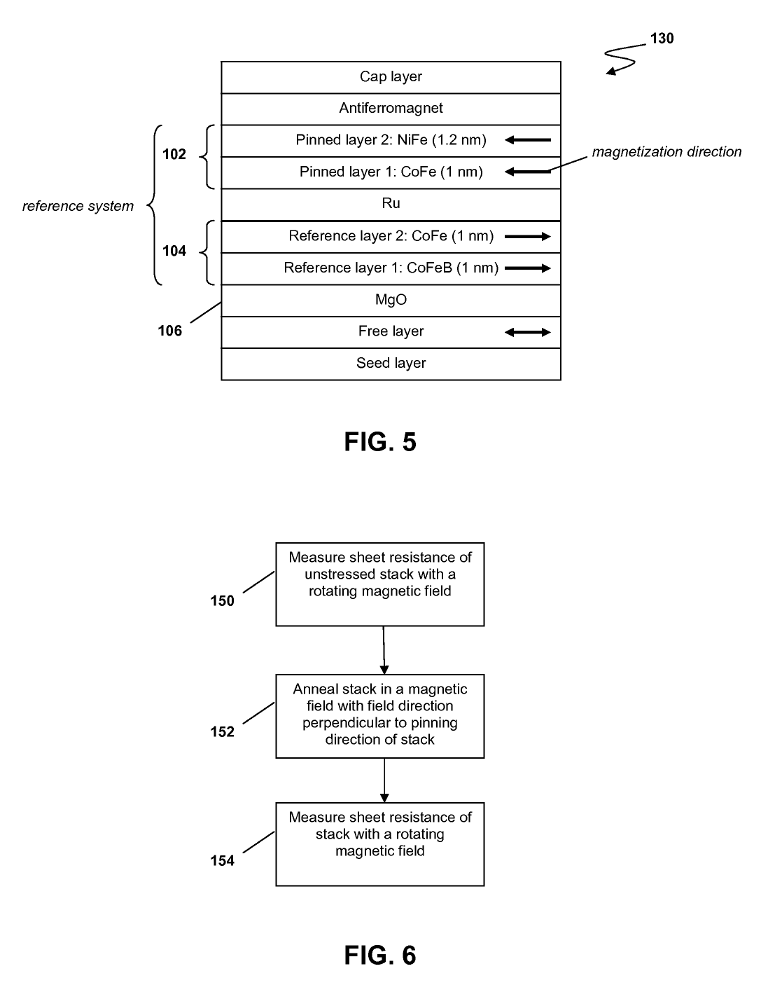

Referring to FIG. 5, another example TMR spin valve layer stack 130 is depicted. In stack 130, reference layer 104 comprises reference layer 1 of CoFeB about 1 nm thick and reference layer 2 of CoFe about 1 nm thick.

Stress test simulations have been performed for various embodiments, with good results. Referring to FIG. 6, stress tests include, at 150, measuring the sheet resistance of the unstressed stack with a rotating magnetic field. The resistance versus the angle, φ, results in a sinus curve: R=R0+A*sin(φ) At 152, the stack is annealed in a magnetic field with the field direction perpendicular to the pinned direction of the stack. At 154, the sheet resistance of the stack is measured again with a rotating magnetic field. Here, R versus the angle φ provides a sinus curve with a phase shift φ0: R=R0+A*sin(φ+φ0). The phase shift φ0 is a measure of the stability of the stack. Results close to 0 degrees would indicate a very stable system, while those close to or greater than 10 degrees would be considered weak.

Embodiments were thus subjected to a stress temperature of 150 degrees C. and a stress field of 1T for a stress time of one hour. A conventional stack presented a φ0 of about 5 degrees to about 9 degrees. A multi-layer embodiment, such as stack 100 of FIG. 2, showed an improved φ0 of only about 2 degrees to about 5 degrees.

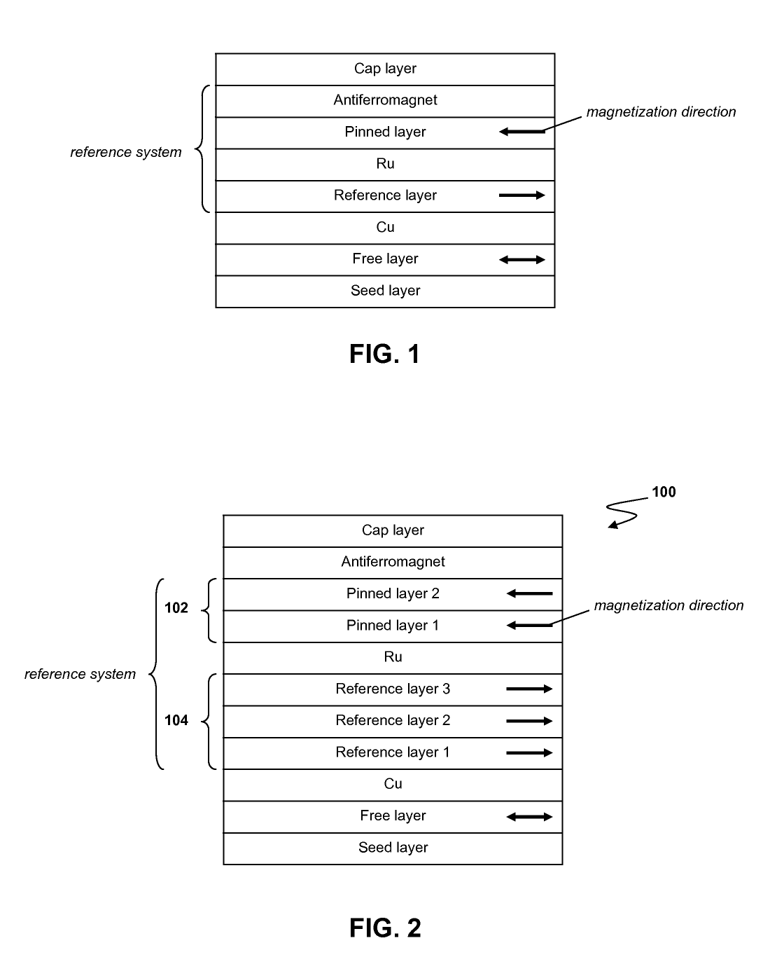

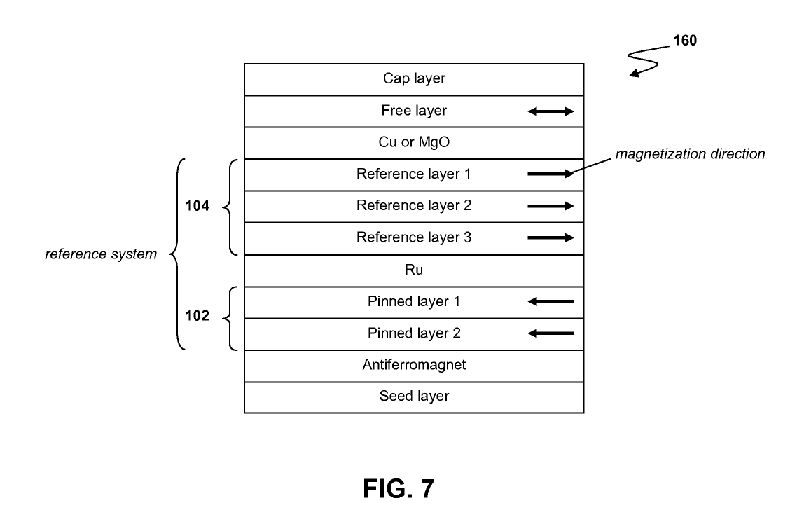

While FIGS. 1-5 generally depict top spin valve stacks, embodiments also relate to bottom spin valve stacks. Differences between top and bottom spin valve stacks relate to the order of the layers. In contrast with the top spin valve stack embodiments of FIGS. 1-5, an embodiment of a bottom spin valve stack 160 depicted in FIG. 7 comprises, from top to bottom, a cap layer; a free layer; a Cu (GMR) or MgO (TMR) layer; a reference layer 104, such as a multi-layer reference layer; an Ru or other nonmagnetic metal layer; a pinned layer 102, such as a multi-layer pinned layer; an antiferromagnet layer; and a seed layer. In embodiments having multi-layer pinned and/or reference layers 102, 104, pinned layer 1 is adjacent to the Ru layer, pinned layer 2 is adjacent to the antiferromagnet layer, reference layer 1 is adjacent the Cu or MgO layer, and reference layer 3 is adjacent the Ru layer.

Embodiments thus relate to magnetoresistive, such as GMR or TMR, spin valve layer systems and related sensors having improved stability. Embodiments comprise at least one of a multi-layer pinned layer or a multi-layer reference layer, making the stack more stable and therefore suitable for use at higher temperatures and magnetic fields than conventional systems and sensors.

Various embodiments of systems, devices and methods have been described herein. These embodiments are given only by way of example and are not intended to limit the scope of the invention. It should be appreciated, moreover, that the various features of the embodiments that have been described as well as of the claims may be combined in various ways to produce numerous additional embodiments. Moreover, while various materials, dimensions, shapes, implantation locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention may comprise a combination of different individual features selected from different individual embodiments and/or from different claims, as understood by persons of ordinary skill in the art.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A magnetoresistive (MR) spin valve layer stack comprising:
an antiferromagnet layer;
a multi-layer pinned layer adjacent the antiferromagnet layer;
a multi-layer reference layer;
a nonmagnetic metal layer between the multi-layer pinned layer and the multi-layer reference layer;
a free layer; and
a nonmagnetic metal layer between the free layer and the multi-layer reference layer.

2. The MR spin valve layer stack of claim 1, wherein the multi-layer pinned layer comprises at least two layers.

3. The MR spin valve layer stack of claim 2, wherein the multi-layer pinned layer has a thickness in a range of about 0.4 nanometers (nm) to about 4 nm.

4. The MR spin valve layer stack of claim 2, wherein the multi-layer pinned layer comprises at least one cobalt iron (CoFe) layer and at least one nickel iron (NiFe) layer.

5. The MR spin valve layer stack of claim 2, wherein the multi-layer pinned layer increases a stability of the MR spin valve layer stack by reducing a stress test phase shift of the MR spin valve layer stack.

6. The MR spin valve layer stack of claim 1, wherein the multi-layer reference layer comprises at least two layers.

7. The MR spin valve layer stack of claim 6, wherein the multi-layer reference layer has a thickness in a range of about 0.9 nanometers (nm) to about 5 nm.

8. The MR spin valve layer stack of claim 6, wherein the multi-layer reference layer comprises three layers.

9. The MR spin valve layer stack of claim 8, wherein the multi-layer reference layer comprises at least one cobalt iron (CoFe) layer and at least one nickel iron (NiFe) layer.

10. The MR spin valve layer stack of claim 8, wherein the multi-layer reference layer further comprises a cobalt iron boron (CoFeB) layer.

11. The MR spin valve layer stack of claim 1, wherein the nonmagnetic metal layer between the free layer and the multi-layer reference layer comprises copper.

12. The MR spin valve layer stack of claim 11, wherein the MR spin valve layer stack comprises a giant MR (GMR) spin valve layer stack.

13. The MR spin valve layer stack of claim 1, wherein the nonmagnetic metal layer between the free layer and the multi-layer reference layer comprises magnesium oxide (MgO).

14. The MR spin valve layer stack of claim 13, wherein the MR spin valve layer stack comprises a tunneling MR (TMR) spin valve layer stack.

15. The MR spin valve stack of claim 1, wherein the nonmagnetic metal layer between the multi-layer pinned layer and the multi-layer reference layer comprises at least one of ruthenium (Ru), iridium (Ir), copper (Cu), rhodium (Rh), osmium (Os), or chromium molybdenum (CrMo).

16. A method of forming a giant magnetoresistive (GMR) spin valve layer stack comprising:
forming a seed layer;
forming a free layer, a first side of the free layer being adjacent a first side of the seed layer;
forming a copper (Cu) layer, a first side of the Cu layer being adjacent a second side of the free layer;
forming a multi-layer reference layer, a first side of the multi-layer reference layer being adjacent a second side of the Cu layer;
forming a nonmagnetic metal layer, a first side of the nonmagnetic metal layer being adjacent a second side of the multi-layer reference layer;
forming a multi-layer pinned layer, a first side of the multi-layer pinned layer being adjacent a second side of the nonmagnetic metal layer;
forming an antiferromagnet layer, a first side of the antiferromagnet layer being adjacent a second side of the multi-layer pinned layer; and
forming a cap layer, a first side of the cap layer being adjacent a second side of the antiferromagnet layer.

17. The method of claim 16, wherein forming a multi-layer reference layer further comprises:
forming a first reference layer, a first side of the first reference layer being the first side of the multi-layer reference layer;
forming a second reference layer, a first side of the second reference layer being adjacent a second side of the first reference layer; and
forming a third reference layer, a first side of the third reference layer being adjacent a second side of the second reference layer and a second side of the third reference layer being the second side of the multi-layer reference layer.

18. The method of claim 17, wherein forming a multi-layer reference layer further comprises:
forming the first reference layer of cobalt iron (CoFe);
forming the second reference layer of nickel iron (NiFe); and
forming the third reference layer of CoFe.

19. The method of claim 16, wherein forming a multi-layer pinned layer further comprises:
forming a first pinned layer, a first side of the first pinned layer being the first side of the multi-layer pinned layer; and
forming a second pinned layer, a first side of the second pinned layer being adjacent a second side of the first pinned layer and a second side of the second pinned layer being the second side of the multi-layer pinned layer.

20. The method of claim 19, wherein forming a multi-layer pinned layer further comprises:
forming the first pinned layer of cobalt iron (CoFe); and
forming the second pinned layer of nickel iron (NiFe).

21. The method of claim 16, wherein forming a nonmagnetic metal layer comprises forming a layer comprising at least one of ruthenium (Ru), iridium (Ir), copper (Cu), rhodium (Rh), osmium (Os), chromium molybdenum (CrMo).

22. A method of forming a tunneling magnetoresistive (TMR) spin valve layer stack comprising:
forming a seed layer;
forming a free layer, a first side of the free layer being adjacent a first side of the seed layer;
forming an insulating layer, a first side of the insulating layer being adjacent a second side of the free layer;
forming a multi-layer reference layer, a first side of the multi-layer reference layer being adjacent a second side of the insulating layer;
forming a nonmagnetic metal layer, a first side of the nonmagnetic metal layer being adjacent a second side of the multi-layer reference layer;
forming a multi-layer pinned layer, a first side of the multi-layer pinned layer being adjacent a second side of the nonmagnetic metal layer;
forming an antiferromagnet layer, a first side of the antiferromagnet layer being adjacent a second side of the multi-layer pinned layer; and
forming a cap layer, a first side of the cap layer being adjacent a second side of the antiferromagnet layer.

23. The method of claim 22, wherein forming a multi-layer reference layer further comprises:
forming a first reference layer, a first side of the first reference layer being the first side of the multi-layer reference layer; and
forming a second reference layer, a first side of the second reference layer being adjacent a second side of the first reference layer and a second side of the second reference layer being the second side of the multi-layer reference layer.

24. The method of claim 23, wherein forming a multi-layer reference layer further comprises:
forming the first reference layer of cobalt iron boron (CoFeB); and
forming the second reference layer of cobalt iron (CoFe).

25. The method of claim 22, wherein forming a multi-layer reference layer further comprises:
forming a first reference layer, a first side of the first reference layer being the first side of the multi-layer reference layer;
forming a second reference layer, a first side of the second reference layer being adjacent a second side of the first reference layer; and
forming a third reference layer, a first side of the third reference layer being adjacent a second side of the second reference layer and a second side of the third reference layer being the second side of the multi-layer reference layer.

26. The method of claim 25, wherein forming a multi-layer reference layer further comprises:
forming the first reference layer of cobalt iron boron (CoFeB);
forming the second reference layer of nickel iron (NiFe); and
forming the third reference layer of CoFe.

27. The method of claim 22, wherein forming a multi-layer pinned layer further comprises:
forming a first pinned layer, a first side of the first pinned layer being the first side of the multi-layer pinned layer; and
forming a second pinned layer, a first side of the second pinned layer being adjacent a second side of the first pinned layer and a second side of the second pinned layer being the second side of the multi-layer pinned layer.

28. The method of claim 27, wherein forming a multi-layer pinned layer further comprises:
forming the first pinned layer of cobalt iron (CoFe); and
forming the second pinned layer of nickel iron (NiFe).

29. The method of claim 22, wherein forming a nonmagnetic metal layer comprises forming a layer comprising at least one of ruthenium (Ru), iridium (Ir), copper (Cu), rhodium (Rh), osmium (Os), chromium molybdenum (CrMo).

30. The method of claim 22, wherein forming an insulating layer comprises forming a magnesium oxide (MgO) layer.

31. A magnetoresistive (MR) spin valve layer stack comprising:
a free layer;
a non-magnetic layer adjacent the free layer;
a reference system adjacent the non-magnetic layer and comprising a reference layer, a nonmagnetic metal layer and a pinned layer, at least one of the reference layer or the pinned layer being a multi-layer; and
an antiferromagnet layer adjacent the reference system.

32. The MR spin valve layer stack of claim 31, wherein a layer of the reference system interfacting the non-magnetic layer and a layer of the pinned layer interfacing the non-magnetic layer comprise the same material.

33. The MR spin valve layer stack of claim 31, wherein the pinned layer comprises a first layer comprising a first material and a second layer comprising a second material, the second layer interfacing the antiferromagnet layer, wherein the first material has a first magnetic coupling characteristic with respect to the antiferromagnet layer, and the second material has a second magnetic coupling characteristic with respect to the antiferromagnet layer, the first magnetic coupling characteristic being weaker than the second magnetic coupling characteristic.

34. The MR spin valve layer stack of claim 31, wherein the pinned layer is a multi-layer comprising a cobalt iron (CoFe) layer and a nickel iron (NiFe) layer, the NiFe layer being adjacent the antiferromagnet.

35. The MR spin valve layer stack of claim 32, wherein the reference layer is a multi-layer comprising at least one cobalt iron (CoFe) layer.

36. The MR spin valve layer stack of claim 31, wherein the non-magnetic layer comprises one selected from the group consisting of copper (Cu) and magnesium oxide (MgO).

37. The method of claim 31, wherein forming a nonmagnetic metal layer comprises forming a layer comprising at least one of ruthenium (Ru), iridium (Ir), copper (Cu), rhodium (Rh), osmium (Os), chromium molybdenum (CrMo).
